(19) United States
(12) Patent Application Publication
(10) Pub. No.: US 2022/0131056 A1
(43) Pub. Date: Apr. 28, 2022

(54) UV LED Package Having Encapsulating Extraction Layer

(71) Applicant: TSLC CORPORATION, Chu-Nan (TW)

(72) Inventors: TZU-YING LIN, HSINCHU CITY (TW); PO-WEI LEE, TAIPEI CITY (TW); SHENG-LUNG CHANG, HSINCHU COUNTY (TW); TZU-HAN LIN, Zhubei City (TW)

(73) Assignee: TSLC CORPORATION, Chu-Nan (TW)

(21) Appl. No.: 17/527,225

(22) Filed: Nov. 16, 2021

Related U.S. Application Data
(62) Division of application No. 16/598,061, filed on Oct. 10, 2019.

(51) Int. Cl. H01L 33/58; H01L 33/48; H01L 33/44

(52) U.S. Cl. CPC H01L 33/58; H01L 33/486; H01L 2933/0025; H01L 2933/0058; H01L 33/44

(57) ABSTRACT

A UV LED package includes a substrate having a dam, a LED die on the substrate, a lens bonded to the substrate, an extraction layer covering a light emitting surface of the LED die, and a lens sealing layer between the lens and the dam. The extraction layer can be formed to provide a precise gap G between the lens and the light emitting diode (LED). In addition, the materials for the lens and the extraction layer can be selected, and the gap G can be precisely dimensioned, to reduce refraction and reflection, to improve radiation extraction, to reduce power radiance, and to improve the efficiency of the UV LED package.

### CROSS REFERENCE TO RELATED APPLICATIONS

This application is a division of Ser. No. 16/598,061, filed Oct. 10, 2019, which is incorporated herein by reference.

### BACKGROUND

This disclosure relates generally to light emitting devices (LEDs) configured to emit UV light and more particularly to UV LED packages.

UV LEDs are used in a variety of systems that exploit the interaction between UV radiation and biological material. These systems can include package sterilization systems for products such as cosmetics, water purification systems and medical devices. A UVC LED will destroy organic materials including any organic materials that are used to construct the package that houses the UVC LED. FIG. 1 illustrates a conventional prior art UVC LED package 10. The UVC LED package 10 includes a ceramic substrate 12 and a light emitting diode (LED) die 14 on the ceramic substrate 12. The UVC LED package 10 also includes a copper dam 16 and a quartz lens 20 bonded to the copper dam 16 using AuSn eutectic bonding layers 18. An air or vacuum space 22 separates the light emitting diode (LED) die 14 from the quartz lens 20. The UVC LED package 10 uses a large amount of power because the emission radiation, as indicated by the emitted light 24, is reduced by refraction and reflection, as indicated by the reflected light 26. The refraction and reflection are high due to the construction of the UVC LED package 10. In particular, the emitted radiation must pass through the space 22 having a reflecting index of 1.0 for air, and into the quartz lens 20 having a reflecting index of 1.5 for quartz, thus increasing the reflected light 26. The reflected light 26 reduces the emitted light 24 and thus the power radiance of the UVC LED package 10 by 15-25%.

In view of the foregoing, there is a need in the art for improved UV LED packages with decreased reflectivity and increased power radiance.

### SUMMARY

A UV LED package includes a substrate having a dam, a LED die bonded to the substrate having a radiation emitting surface configured to emit radiation in the UV spectrum, an extraction layer on the radiation emitting surface, a lens on the extraction layer, and a lens sealing layer between the lens and the dam. The extraction layer comprises a transparent and high UV transmission material that does not degrade with UV radiation. In addition, a material and thickness of the extraction layer can be selected to reduce refraction and reflection and to improve radiation extraction from the LED die. This in turn reduces power radiance and improves the efficiency of the UV LED package. Suitable materials for the extraction layer include polymers, glasses, and oxides. The lens sealing layer can comprise a same material as the extraction layer.

A method for fabricating the UV LED package includes the steps of providing a substrate having a dam, bonding a LED die configured to emit UV radiation to the substrate within the dam, forming an extraction layer on a radiation emitting surface of the LED die, bonding a lens to the extraction layer, and forming a lens sealing layer between the lens and the dam. A material and a thickness t of the extraction layer can be selected to increase radiation extraction from the LED die and to provide a gap G between the LED die and the lens, such that refraction and reflection are reduced.

A UVC lamp can include one or more UV LED packages on a circuit substrate.

### BRIEF DESCRIPTION OF THE DRAWINGS

Exemplary embodiments are illustrated in the referenced figures of the drawings. It is intended that the embodiments and the figures disclosed herein are to be considered illustrative rather than limiting.

FIG. 1 is a schematic cross sectional view of a prior art UVC LED package;

FIG. 2 is a schematic cross sectional view of a UV LED package;

FIGS. 3A-3G are schematic cross sectional views illustrating steps in the fabrication of the UV LED package;

FIG. 4 is a schematic cross sectional view illustrating operational characteristics of the UV LED package;

FIG. 5A is a schematic cross sectional view of the UV LED package incorporated into a UVC lamp; and

FIG. 5B is an enlarged portion of FIG. 6A illustrating further details of the UVC lamp.

### DETAILED DESCRIPTION

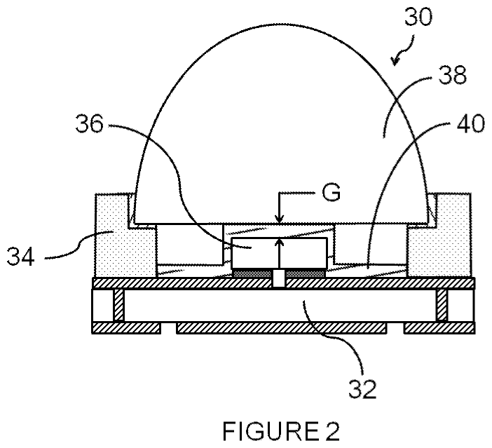

Referring to FIG. 2, a UV LED package 30 includes a substrate 32 having a dam 34, a LED die 36 on the substrate 32, an extraction layer 40 on the LED die 36, a lens 38 on the extraction layer 40, and a lens sealing layer 54 between the dam 34 and the lens 38. The extraction layer 40 comprises a transparent and high UV transmission material that preferably also attaches the lens 38 to the substrate 32. The extraction layer increases radiation extraction from the LED die 36 and forms a precisely dimensioned gap G between the LED die 36 and the lens 38. Further details of the UV LED package 30 will become more apparent as the description proceeds.

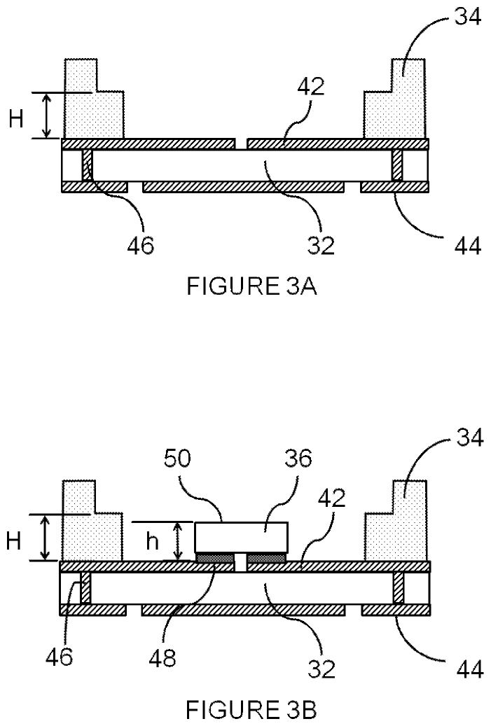

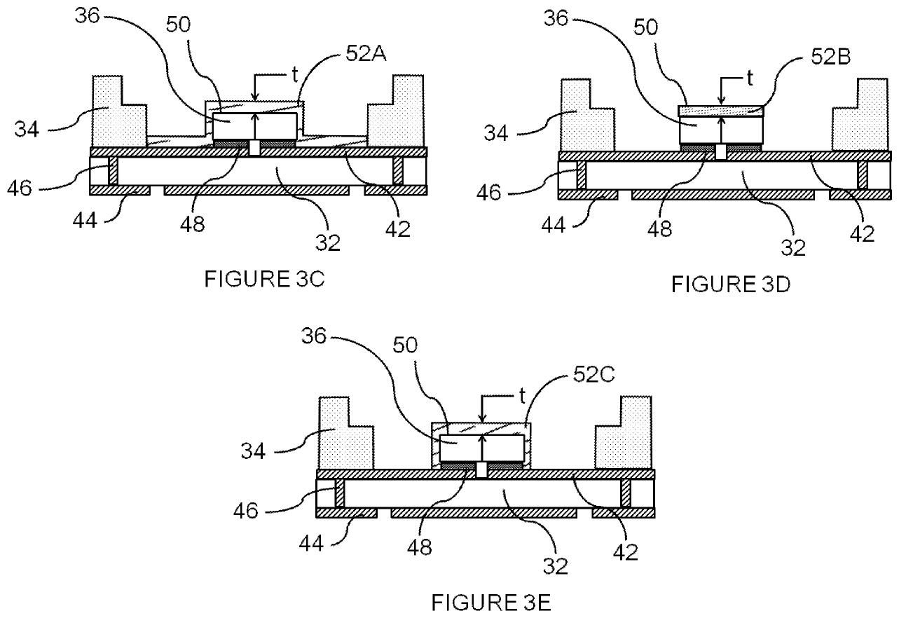

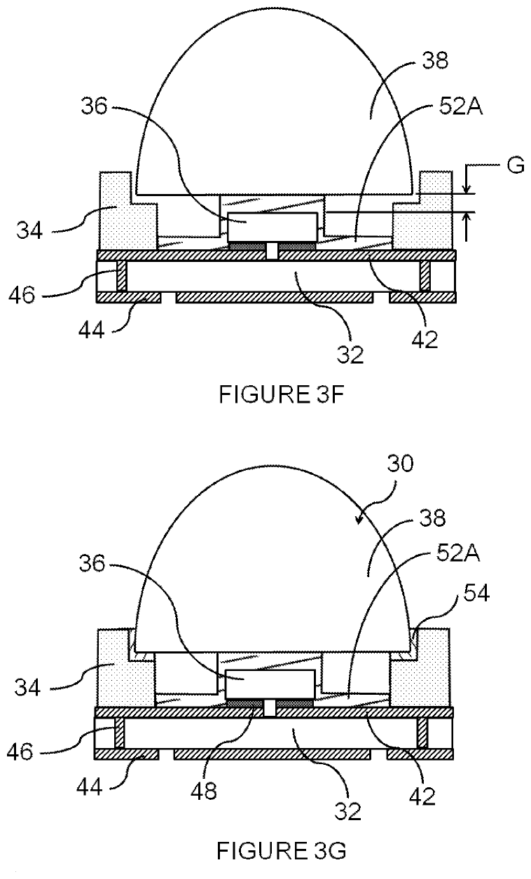

Referring to FIGS. 3A-3G, steps in a method for fabricating the UV LED package 30 (FIG. 2) are illustrated. Initially as shown in FIG. 3A, the method includes the step of providing a substrate 32. Suitable materials for the substrate 32 include ceramic materials such as AlN and Al2O3. The substrate 32 includes a top side metal layer 42, a back side metal layer 44 and conductive vias 46 that electrically interconnect the top side metal layer 42 with the back side metal layer 44. The top side metal layer 42 and the back side metal layer 44 can include contacts for electrically interconnecting elements of the UV LED package 30 (FIG. 2) and for bonding and electrically connecting the UV LED package 30 (FIG. 2) in an electrical system, such as a UV lamp. Suitable metals for the top side metal layer 42 and the back side metal layer 44 include Au, Ag, Cu, Ni, and Ni/Pd/Au alloys formed in desired patterns using a suitable deposition process. The conductive vias 46 can comprise through holes filled with Au, Ag, Cu or Ni. In addition, the substrate 32 can have any desired peripheral outline, such as square, rectangular or polygonal. Further, the size of the substrate 32 can be selected as required, with a chip scale size being representative.

Still referring to FIG. 3A, the dam 34 can comprise a material deposited on the substrate 32, or can be formed integrally as a portion of the substrate 32. For example, the dam 34 can comprise Cu or Al deposited on the substrate 32 using a suitable deposition process such as CVD or PECVD. As another example, the dam 34 can comprise an integral portion of the substrate 32 formed during fabrication of the substrate 32 out of the same ceramic material. The dam 34 can have a peripheral outline that matches the peripheral outline of the substrate 32 and ultimately determines the outside edge and peripheral outline of the UV LED package 30 (FIG. 2). In addition, the dam 34 can have a desired height H on the substrate 32 measured from the surface of the top side metal layer 42. Further, the dam 34 can be dimensioned and shaped to precisely locate the lens 38 on the substrate 32 with respect to the LED die 36.

Referring to FIG. 3B, the method also includes the step of bonding the LED die 36 to the substrate 32. This step is sometimes referred to in the art as die bonding, and can be accomplished using techniques and equipment that are known in the art. For example, the bonding step can be performed using a suitable bonding layer 48 made of a material, such as AuSn, silver paste or a Sn alloy. Also in the illustrative embodiment, the LED die 36 comprises a flip chip LED die. However, the LED die can have other desired configurations such as a vertical LED die or a horizontal LED die. In any case, the LED die 36 is configured to emit a desired wavelength of UV radiation (e.g., UVC 100-280 nm) from a radiation emitting surface 50. The bonding step can be controlled such that the LED die 36 has a height h on the substrate 32 measured from the surface of the top side metal layer 42. The height h is less than the height H of the dam 34 and is dimensioned to provide a precise gap G (FIG. 3F) between the radiation emitting surface 50 of the LED die 36 and the lens 38 (FIG. 3F). By way of example, the gap G (FIG. 3F) can be under 50 μm.

Referring to FIGS. 3C-3E, the step of forming an extraction layer 52A-52C on the radiation emitting surface 50 of the LED die 36 are illustrated in alternate versions. In FIG. 3A, an extraction layer 52A encapsulates the LED die 36 and the top side metal layer 42 on the substrate 32. In FIG. 3B, an extraction layer 52B only covers the radiation emitting surface 50 of the LED die 36. In FIG. 3C, an extraction layer 52C completely encapsulates the LED die 36. The extraction layer 52A-52C comprises a material configured to increase radiation extraction from the LED die 36. In addition, the extraction layer 52A-52C comprises a material that is highly transparent and transmissive to UV radiation in the selected wavelength range. Additionally, the extraction layer 52A-52C comprises a material that is able to resist damage and degradation by UV radiation, particularly UVC radiation. Further, the extraction layer 52A-52C can comprise a material that functions as an adhesive layer for bonding the lens 38 to the ceramic substrate 32. Still further, the extraction layer 52A-52C comprises a material that can deposited to a precise and planar thickness t that determines the gap G (FIG. 3F).

Suitable materials for the extraction layer 52A-52C include polymers, glasses, such as a spin-on-glass (SOG), and oxides, such as SiO2. Depending on the material, the extraction layer 52A-52C can be formed using a thin film deposition process, such as CVD or PECVD, or in the case of a spin-on-glass, a spin on process. As with the gap G the thickness t can be under 50 μm. The extraction layer 52A-52C can comprise an inorganic polymer, an organic polymer, or a hybrid polymer having a high UV resistance. Specific polymers for forming the extraction layer 52A-52C include fluorinated polymers, such as fluorinated polyimide, and hybrid polymers, such as Teflon and polyimides having light stabilizer additives.

Referring to FIG. 3F, the step of bonding the lens 38 to the substrate 32 is illustrated. The lens bonding step can be performed by placing the lens on the extraction layer 52A-52C, which can also be configured to perform an adhesive function. For example, with the extraction layer 52A-52C comprising a polymer material, the lens bonding step can be performed placing the lens 38 on a semi solid or viscous layer of material, followed by curing to harden the extraction layer 52A-52C and bond the lens 38. Alternately a separate polymer adhesive layer (not shown) can be used to bond the lens 38 to the extraction layer 52A-52C. The lens 38 can have any desired shape, such as a convex shape in a 30, 60, 90, 120 or 140 degree configuration. As another example, the lens 38 can have a flat planar shape.

Referring to FIG. 3G, the step of sealing the lens 38 to the dam 34 is illustrated. The lens sealing step can be performed by coating the sidewalls of the dam to form the lens sealing layer 54. Preferably the lens sealing layer 54 comprises the same material as the extraction layer 52A-52C, and can be formed using a suitable deposition process, such as CVD, PECVD, spin-on or deposition through a nozzle. Further, the substrate 32 and the dam 34 can be constructed to precisely locate the lens 38, the extraction layer 52A-52C and the LED die 36.

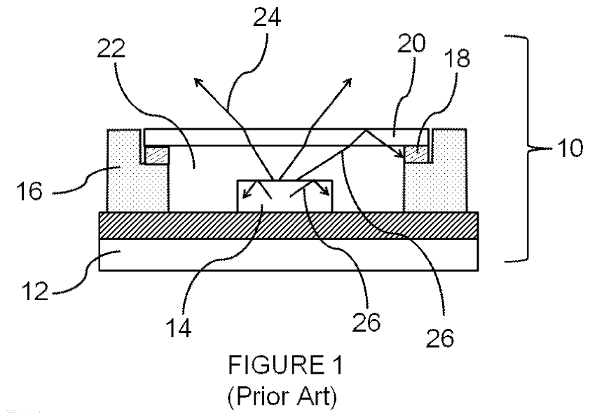

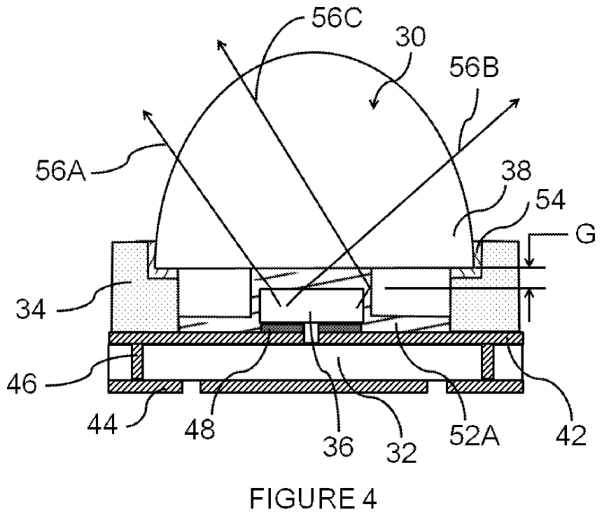

Referring to FIG. 4, operational characteristics of the UV LED package 30 (FIG. 2) are illustrated. In FIG. 4, the radiation emitted by the light emitting diode (LED) 36 is illustrated by light rays 56A-56C. Light rays 56A and 56C transmit directly from the radiation emitting surface 50 of the LED die 36, through the extraction layer 52A, and then through the lens 38 with almost no refraction or reflection. In addition, light rays 56B are refracted and reflected (i.e., total reflection) by the extraction layer 52A on the sidewalls of the light emitting diode 36 and transmit closer to the optical center of the lens 38. The materials for the lens 38 and the extraction layer 52A can be selected, and the gap G can be precisely dimensioned, to reduce refraction and reflection, to improve radiation extraction, to reduce power radiance, and to improve the efficiency of the UV LED package 30 (FIG. 2). In testing by the inventors, the UV LED package 40 (FIG. 2) can have a power radiance reduction of between 15%-25% and a radiation extraction increase of between 10%-50% compared to the prior art UV LED package 10 (FIG. 1). In addition, an efficiency of the UV LED package 30 (FIG. 2) can be increased by 25% to 75% compared to the prior art UV LED package 10 (FIG. 1).

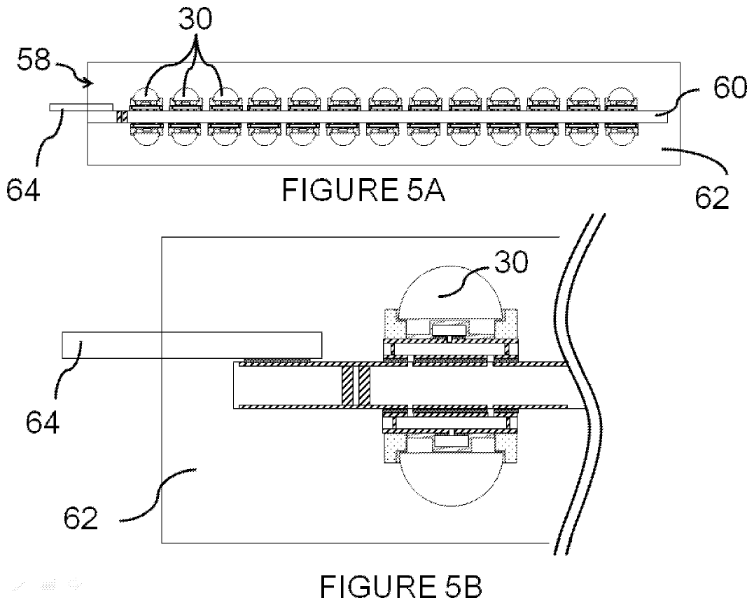

Referring to FIGS. 5A and 5B, a UV lamp 58 includes a quartz bulb 62 and a plurality of UV LED package 30 mounted to a circuit board 60 having an external connector 64 configured as a power input pin.

Thus the disclosure describes an improved UV LED package and method of fabrication. While a number of exemplary aspects and embodiments have been discussed above, those of skill in the art will recognize certain modifications, permutations, additions and subcombinations thereof. It is therefore intended that the following appended claims and claims hereafter introduced are interpreted to include all such modifications, permutations, additions and sub-combinations as are within their true spirit and scope.

What is claimed is:

1. A UV LED package comprising:
a substrate comprising a dam;
a LED die bonded to the substrate inside of the dam configured to emit UV radiation from a radiation emitting surface;
an extraction layer comprising a fluorinated polymer encapsulating the LED die and the radiation emitting surface of the LED die, the extraction layer configured to extract radiation from the LED die while resisting damage and degradation by the UV radiation;
a lens bonded to the extraction layer; and
a lens sealing layer between the lens and the dam,
the dam dimensioned and shaped to locate the lens on the substrate with respect to the LED die.

2. The UV LED package of claim 1 wherein the extraction layer has a thickness on the radiation emitting surface of the LED die selected to form a gap between the radiation emitting surface and the lens.

3. The UV LED package of claim 1 wherein the substrate comprises a ceramic and the dam comprises a ceramic portion of the substrate.

4. The UV LED package of claim 1 wherein the dam comprises a deposited metal on the substrate.

5. A UV LED package comprising:
a substrate comprising a top side metal layer, a back side metal layer, conductive vias and a dam;
a LED die bonded to the substrate inside of the dam in electrical communication with the top side metal layer, the LED die configured to emit UVC radiation from a radiation emitting surface;
an extraction layer comprising a fluorinated polymer encapsulating the LED die and the top side metal layer of the substrate, the extraction layer having a portion covering the radiation emitting surface of the LED die with a thickness of t, the extraction layer configured to extract radiation from the LED die while resisting damage and degradation by the UVC radiation;
a lens bonded to the portion of the extraction layer covering the radiation emitting surface of the LED die such that a gap G between the lens and the radiation emitting surface of the LED die is equal to the thickness t of the extraction layer;
a lens sealing layer between the lens and the dam,
the dam dimensioned and shaped to locate the lens on the substrate with respect to the LED die.

6. The UV LED package of claim 5 wherein the thickness t of the extraction layer is less than 50 μm.

7. The UV LED package of claim 5 wherein the substrate comprises a ceramic and the dam comprises a ceramic portion of the substrate.

8. The UV LED package of claim 5 wherein the dam comprises a deposited metal on the substrate.
